(19) United States
(12) Patent Application Publication
(10) Pub. No.: US 2022/0342013 A1
(43) Pub. Date: Oct. 27, 2022

(54) Measuring device and method for determining magnetic properties of a magnetizable test specimen

(71) Applicant: Bs & T Frankfurt am Main GmbH, Frankfurt am Main (DE)

(72) Inventor: Jun Chao SUN, Frankfurt am Main (DE)

(73) Assignee: Bs & T Frankfurt am Main GmbH, Frankfurt am Main (DE)

(21) Appl. No.: 17/727,468

(22) Filed: Apr. 22, 2022

(30) Foreign Application Priority Data
Apr. 23, 2021 (DE) 10 2021 110 527.7

(51) Int. Cl. G01R 33/12; G01R 33/00; H01F 13/00

(52) U.S. Cl. CPC G01R 33/12; G01R 33/0011; H01F 13/00

(57) ABSTRACT

A measuring device for determining magnetic properties of a magnetizable test specimen comprises a measuring coil winding which passes around a magnetizable measuring coil core. The measuring coil core comprises magnetic flux passage faces arranged at a distance from one another. The test specimen is arranged adjacently to the magnetic flux passage faces. A high-current pulse through the measuring coil winding causes a magnetic flux through the measuring coil core and the test specimen. A temporal profile of electrical characteristic variables of the measuring coil winding is detected using a sensor device. The electrical characteristic variables of the measuring coil winding detected by the sensor device are set in a ratio to additionally ascertained electrical characteristic variables of the measuring coil winding without the test specimen. A magnetic property of the test specimen is determined from the ratio of the electrical characteristic variables to one another.

### CROSS-REFERENCE TO RELATED APPLICATION

This application claims the benefit of German Patent Application No. DE 10 2021 110 527.7, filed Apr. 23, 2021, the contents of which is incorporated by reference in its entirety.

### TECHNICAL FIELD

The disclosure relates to a measuring device for determining magnetic properties of a magnetizable test specimen and to a method for detecting magnetic properties of a magnetizable test specimen.

### BACKGROUND

The electrical properties of an electrical component which can be used in an apparatus supplied with electrical energy are of decisive significance for the electrical component in question. This is also true similarly for electronic components and electronic circuits, which in the following will not be mentioned and described separately but will be referred to collectively and by way of simplification as electrical circuits and electrical components.

The use of soft-magnetic materials is gaining increasingly here in importance for the production and design of compact and low-loss electrical components and in particular for electrical components in the field of power electronics, which can be used for the transformation of electrical energy in respect of the voltage waveform, the voltage and current levels, and also the frequency. Here, in many cases, the saturation behavior as well as a power loss of a soft-magnetic material that occurs during operation are key properties of an inductive electrical component produced from or with a soft-magnetic material of this kind. The inductive properties of soft-magnetic materials of this kind, or quite generally of magnetic materials are therefore detected using various measurement methods and measurement apparatuses in order to be able to identify the most suitable materials possible for the particular intended use of an electrical component.

For standardized components or component parts which are to be manufactured in large quantities, it may be of great economic importance that the materials used for the production and in particular soft-magnetic materials are checked and tested as comprehensively as possible in order to avoid a relatively large number of components, some of which are complex and costly to produce, not having the desired properties or not being able to perform functions on account of material errors.

Due to many non-linear effects of an electromagnetic behavior of the component parts, high demands may be placed on the measuring devices used for a material check performed prior to the manufacturing process or for a final control performed following the manufacturing process. The measuring devices used for this purpose must be able to measure the relevant properties quickly and accurately over the entire working range of the component parts to be measured, in order to economically ensure the quality of the produced component parts.

For example, document DE 10 2018 127 378 B3 discloses a measuring method, a measuring apparatus and a data carrier with measurement data for determining an inductance of an electrical component. In the method, in order to determine the inductance L of the electrical component using the measuring apparatus, a high-current pulse is generated in an excitation step and is conducted through the electrical component. The electronic component is arranged together with a reference component and with at least one capacitor in an electrical resonant circuit, which is excited to perform electrical vibrations by at least one high-current pulse. In a measuring step, electrical properties of the electrical component are measured over a measurement period, and in an evaluation step the inductance L of the electrical component is determined from the measured electrical properties. Here, in the measurement step, a voltage drop U across the electrical component and a reference voltage drop U across the reference component connected in series to the electrical component and having a known reference inductance L are measured. In the evaluation step, the inductance L of the electrical component is calculated as the product of the reference inductance L with a proportionality factor that is dependent on the measured voltage drop U and the measured reference voltage drop U.

In particular in the case of components that are complex to produce and that have magnetic properties, or in the case of functional components, it is often economically advantageous if the magnetic properties of the materials and semi-finished products provided for the production are checked already before the production of the component. Materials and semi-finished products that are inferior and do not satisfy the quality requirements can therefore be rejected or marked before they are processed into a finished component part.

An often-used semi-finished product, for which it is advantageous to know its magnetic properties and characteristic variables in good time and prior to processing into a component part, is an electrical sheet. Here, electrical sheets are soft-magnetic materials for magnetic cores, for example in electric motors or transformers. Here, it is important for the intended function, for example of the transformer, to know the total magnetic power loss of the transformer core, which is routinely constructed from a plurality of layered electrical sheets. This is because the transformer has been produced and constructed, individual electrical sheets can no longer be replaced in the transformer core in an economically viable manner or without destruction.

Document DE 10 2019 109 337 B3 discloses an apparatus and a method for measuring magnetic properties of a ferromagnetic endless strip, from which the electrical sheets can be punched out in a subsequent production step. Here, the method is used to determine the magnetic properties of a portion of the magnetizable endless strip, wherein the apparatus comprises a primary coil for generating a magnetic field, a slotted yoke for guiding the magnetic flux, and a plurality of coils for measuring the magnetic flux. The measurement of the magnetic flux with the plurality of coils, however, is considered to be disadvantageous because a magnetic flux can only be measured relatively imprecisely with the aid of coils or other sensors—for example Hall sensors.

### SUMMARY

It is an object of the disclosure to provide a measuring device with which the magnetic properties of a magnetizable test specimen can be measured as precisely, quickly and reliably as possible.

The measuring device for determining magnetic properties of a magnetizable test specimen includes a measuring coil winding which passes around a measuring coil core and can be supplied with electrical energy from an energy supply device. The measuring device further includes a sensor device, by means of which at least one characteristic variable for the magnetic properties of the magnetizable test specimen can be detected.

The energy supply device is designed and set up in such a way that the energy supply device can be used to generate a high-current pulse and to conduct the latter through the measuring coil winding. The measuring coil core comprises at least two magnetic flux passage faces distanced from one another. The magnetizable test specimen, during a measurement process, can be arranged adjacently to the at least two magnetic flux passage faces in such a way that a high-current pulse conductable through the measuring coil winding can bring about a magnetic flux through the magnetizable measuring coil core and the magnetizable test specimen. The sensor device is designed and set up in such a way that the sensor device can be used to detect a temporal profile of electrical characteristic variables of the measuring coil winding.

The high-current pulse can reach a peak value here of several hundred or thousand amperes, wherein it should have a pulse duration from a few to several hundred microseconds. The high-current pulse provided by the energy supply device brings about a magnetic flux in a measuring coil core, which magnetic flux naturally comprises closed field lines. The closed field lines run on the one hand in a concentrated manner along and inside the measuring coil core and on the other hand outside the measuring coil core. If the magnetizable test specimen is arranged at the magnetic flux passage faces such that the field lines of the magnetic flux from one magnetic flux passage face along the path to the other magnetic flux passage face can run largely through the magnetizable test specimen, it allows the field lines of the magnetic flux to have a path of lower magnetic resistance, so that the field lines outside the measuring coil core can be concentrated in the magnetizable test specimen. The magnetic flux of the measuring coil core also concentrated in the test specimen thus significantly influences the total magnetic power loss of the measuring coil core and of the test specimen and thus also significantly the electrical power consumption of the measuring coil winding.

The sensor device detects the current and voltage profiles in the measuring coil winding that are generated by the high-current pulse. Here, the current and voltage profiles are influenced measurably by the inductance of the measuring coil core and of the magnetizable test specimen. The inductance and thus the magnetic overall losses can be determined from the electrical characteristic variables and the profile of the high- current pulse. A possible method for determining the inductance of the measuring coil winding is known from the above-cited document DE 10 2018 127 378 B3. It is possible to conclude the magnetic flux on the basis of an integration of the current profile through the measuring coil winding with an inductance of the measuring coil winding. A measurement with a magnetizable test specimen connecting or bridging the two magnetic flux passage faces of the measuring coil core can be compared with a further measurement without the magnetizable test specimen or with a further measurement of a test specimen of which the magnetic properties are already known and, by way of the comparison, the magnetic properties, which are determinable from magnetic flux, the magnetic field strength and the transient current profile, are ascertained for the magnetizable test specimen. Accordingly, a specific, magnetic power loss of the magnetizable test specimen can be determined on the basis of a comparison or reference measurement of this kind without the magnetizable test specimen.

Electrical instead of magnetic characteristic variables are to be detected for the ascertainment of the magnetic properties, such as the magnetic losses, during a magnetization of the magnetic test specimen. The magnetic characteristic variables of the measuring coil winding and of the measuring coil core can be ascertained or calculated with the aid of known correlations, proceeding from the measured electrical characteristic variables.

The high-current pulse can have transient and periodic signal components, by means of which electrical characteristics of the measuring coil winding, such as the inductance or the resistance, can be determined, on the basis of which the magnetic characteristics of the measuring coil core and the test specimen can then be calculated. Both saturation effects and a frequency behavior of the measuring coil core and of the test specimen can be ascertained on the basis of the high-current pulse.

With a sufficiently strong energy supply device, the test specimen can be measured economically quickly and at the same time very precisely.

In accordance with an advantageous embodiment, it can be provided that the measuring coil core can consist of a material of high magnetic permeability. The magnetizable test specimen and the magnetizable measuring coil core expediently each consist of a material of different magnetic permeability. From a measurement viewpoint it is advantageous if the measuring coil core has a very high quality and thus low magnetic power loss, so that the power loss of the test specimen in the measurement process can become more significant and can be separated more easily from the losses of the measuring coil core.

In respect of a quick checking and measurement of a large material volume, it is optionally provided and advantageous that the magnetizable test specimen is arranged movably at the magnetic flux passage faces. A test specimen movable along the magnetic flux passage faces can thus be measured in certain portions. The test specimen can be moved along the magnetic flux passage faces continuously at a constant speed and thus without interruption. It is likewise possible to stop the magnetizable test specimen at time intervals during an otherwise continuous movement and to perform a measurement in order to then move the magnetizable test specimen and perform a subsequent measurement at a different position or for a different region of the magnetizable test specimen. The magnetic flux passage faces can cooperate with the test specimen in some portions, wherein a more targeted and more detailed measurement of the test specimen can be ensured. Here, the magnetizable test specimen can either be moved past close to the magnetic flux passage faces, but at a distance from the magnetic flux passage faces, or can bear against the magnetic flux passage faces, at least whilst a measurement is being taken, and can have direct contact with the magnetic flux passage faces.

A continuous movement of the magnetizable test specimen is considered to be particularly advantageous if the magnetizable test specimen consists in each case of a portion of an endless strip wound on a roll, from which individual electrical sheet blanks for example can be produced in a subsequent production step, which for example are joined together to form a transformer core.

In this way, a test specimen formed as an endless strip can be measured in some portions, wherein with each individual measurement the magnetic properties of the particular portion can be determined. The regions suitable for a subsequent production process can be identified on the basis of an overview of the magnetic properties of the endless strip measured in this way. Electrical sheet blanks having similar identical magnetic properties can also be combined with one another and used jointly in one component part.

According to an embodiment, it can be provided that the measuring coil core is U-shaped. In the case of a U-shaped measuring coil core, the measuring coil winding can be arranged in a connection portion of the measuring coil core located between two limbs, whereas the magnetic flux passage faces are formed in each case by end faces of the two limbs, so that an elongate test specimen can bridge a distance between the mutually distanced magnetic flux passage faces and the field lines of the magnetic flux can run through the limbs of the U-shaped measuring coil core and through the test specimen bridging the two limbs. A magnetic circuit with closed field lines running in an O shape is thus created by the measuring coil core and the test specimen.

Furthermore, a U-shaped measuring coil core is suitable insofar as the magnetic flux passage faces can be guided more easily along flat test specimens or along a planar surface of the test specimen, wherein the particular test specimen can be measured in some portions.

In order to increase the measurement accuracy it is optionally provided that the magnetic flux passage faces of the measuring coil core have a surface roughness with a mean roughness value of less than 5μm, preferably less than 0.5 μm. By way of a low surface roughness of this kind, an undesirable flux leakage of the magnetic field passing through the two magnetic flux passage faces can be very significantly reduced, whereby the measurement accuracy for the magnetic properties of the test specimen arranged in the vicinity of or also directly against the magnetic flux passage faces can be considerably improved.

In accordance with a particularly advantageous embodiment, it can be provided that the measuring device comprises a second magnetizable measuring coil core which is arranged with its magnetic flux passage faces opposite the magnetic flux passage faces of the first magnetizable measuring coil core passed around by the measuring coil winding, wherein the magnetizable test specimen is arranged between the magnetic flux passage faces of the two magnetizable measuring coil cores, so that the magnetic flux created by the measuring coil winding can act through the two magnetizable measuring coil cores and the magnetizable test specimen.

In accordance with this embodiment, an improved symmetry of the magnetic flux and field lines thereof can be achieved, since the field lines can lead through the two measuring coil cores and the test specimen arranged between the two measuring coil cores. In addition, the second measuring coil core can likewise have a measuring coil winding, which can bring about a second magnetic flux in phase with the first magnetic flux. A greater penetration depth of the magnetic fluxes into the test specimen can thus be achieved, whereby the measurement accuracy optionally can be increased.

An additional detection and determination of the magnetic properties can be achieved in that the measuring device has a magneto-optical sensor device, by means of which a magnetization of the magnetizable test specimen can be detected optically. With a magneto-optical sensor device, it is possible to detect optically the magnetization of a surface region of the magnetizable test specimen. Here, the magneto-optical Kerr effect for example can be utilized, consequently a polarization of light which is reflected by a surface of the test specimen is dependent on the magnetization of the test specimen in the region of the surface. The additional use of a magneto-optical sensor device can be advantageous for example for the purposes of quality control if the electrical characteristic variables measured by the sensor device and detected for a predefined spatial arrangement of the test specimen relative to the magnetic flux passage faces can be compared with the measurement values or images detected with the magneto-optical sensor device. The magneto-optical sensor device allows an additional and spatially often high-resolution ascertainment of the magnetic flux density of the test specimen.

For the most effective possible utilization of the measuring coil winding, it can be provided that the measuring coil winding consists of multicore lines, wherein the lines are electrically insulated with respect to one another. Here, the lines can be insulated for example by way of a coating, which is deposited on a surface of each line, so that none of the lines are electrically connected to one another along the measuring coil winding. Thereafter, parasitic effects caused by the high-current pulse such as a skin effect or a proximity effect in the measuring coil winding, can be reduced so that a best-possible cross-section utilization of the measuring coil winding is achievable.

It is considered to be a further object of the present disclosure to provide a method by which the magnetic properties of a magnetizable test specimen can be ascertained as precisely, quickly and reliably as possible.

The object is achieved by a method for detecting magnetic properties of a magnetizable test specimen, wherein in a measuring step the magnetizable test specimen is arranged in a measuring position relative to a measuring coil core with a measuring coil winding of a measuring device passing around the measuring coil core, and a high-current pulse brought about by the energy supply device is guided through the measuring coil winding of the measuring device by way of an energy supply device which is electrically conductively connected to the measuring device, wherein at least one temporal current and voltage profile through the measuring coil winding is detected, and wherein in a subsequent ascertainment step a characteristic variable for a magnetic property of the test specimen is ascertained on the basis of the at least one detected current and voltage profile in that the current and voltage profile, detected with the magnetizable test specimen, for the magnetizable test specimen and the measuring device is compared with the particular profile of a reference current profile and reference voltage profile measured in a reference measurement step with the measuring device for a reference body, wherein the characteristic variable for the magnetic property of the test specimen is determined on the basis of a difference between the measured current and voltage profile and the reference current and reference voltage profile.

The reference measurement step can be performed for example for air or vacuum as reference body, so that the reference current profile and the reference voltage profile are influenced solely by the inductance of the measuring device. The reference measurement step can also be performed for a reference body deviating from the test specimen in respect of the material or the shaping, wherein in this case, as in the measurement step with the test specimen, the combined inductance of the measuring device and of the reference body influences the profile of the reference current profile and of the reference voltage profile.

Both in the measurement step and in the reference measurement step, all detected electrical characteristic variables and in particular the current and voltage profiles are expediently saved. Starting from this basis, for example the magnetic losses of the test specimen can be calculated.

The reference measurement step can be run through as many times as desired before the measuring device is operated in series, so that enough current and voltage profiles of the measuring coil core are available without the test specimen and possibly in combination with various reference bodies in order to calibrate the measuring device and collect a large amount of reference data. The reference measurement step can optionally also be repeated at periodic intervals in order to be able to ensure a stable quality of the results of the measuring device.

According to an advantageous embodiment of the method, it can be provided that in a movement step the magnetizable test specimen is moved relative to the magnetic flux passage faces of the measuring coil core. The two magnetic flux passage faces of the measuring coil core are expediently planar and oriented in a common measurement plane or at least parallel to one another. The test specimen can be moved parallel to the measurement plane or with a surface of the test specimen along the measurement plane of the magnetic flux passage faces. A continuous measurement sequence and a continuous measurement of some portions of the magnetizable test specimen can thus also be made possible.

It has been found that the method can be performed particularly advantageously for thin-walled metal sheets which are intended for the production of magnetic or electromagnetic component parts, such as transformers. Here, rapidly solidified amorphous or nanocrystalline metal sheets with a thickness of less than 0.1 mm, preferably of less than 0.03 mm are considered to be semi-finished products with particularly favorable properties for the production of magnetic or electromagnetic component parts. Under favorable conditions, metal sheets of this kind with a thickness of approximately 5 μm can also be produced and then measured or checked. Sheets of this kind made of metal or made of a suitable alloy can be produced in the form of an endless strip and checked using the method, prior to the production of individual blanks for component parts, by passing the metal strip continuously past the measuring device and at the same time determining the magnetic properties of the metal strip or by checking the latter at least randomly.

In a movement step, the test specimen can be moved continuously or in steps. With a continuous movement, numerous individual measurements are made possible within a short space of time. With a stepped movement, the test specimen can be measured at discrete intervals and thus within regions predefined in a defined manner.

In accordance with a particularly advantageous embodiment, it can be provided that the high-current pulse generated by the energy supply device and guided through the measuring coil winding is predefined such that a magnetic flux generated in the magnetizable test specimen by the high-current pulse is adapted to a magnetic saturation of the magnetizable test specimen. The greatest possible magnetization of the magnetizable test specimen during a measurement allows a high measurement accuracy. Here, the energy of the high-current pulse is preferably adapted to the magnetizable test specimen such that, due to the high-current pulse a magnetic flux of this kind is generated in the test specimen and the test specimen is thus magnetized such that a magnetic saturation of the region of the test specimen detected by the magnetic field between the two magnetic flux passage faces is brought about. If possible, no excess energy or only a small proportion of excess energy should be introduced here into the magnetizable test specimen, and is then converted for example into kinetic energy and causes the test specimen to vibrate. The energy of the high-current pulse can expediently be predefined with an accuracy of less than 1 Joule and adapted to the sought measurement conditions.

Optionally, a movement or measurement speed of the test specimen can also be predefined in such a way that only a few portions of the test specimen arranged at a distance from one another are purposefully measured. A large number of test specimens can thus be checked within a short space of time and it is possible to estimate on the basis of the few measurements whether the magnetic properties of the test specimen correspond to the specifications. This is advantageous since the time for a complete measurement of each test specimen can be saved and the production speed can be increased.

Optionally, according to a particularly advantageous embodiment of the method, it can be provided that in a magnetic field detection step a magnetic flux density of the magnetic field detectable using a magneto-optical sensor device is detected at a surface of the test specimen. The magnetic field detection step can be performed here efficiently in parallel with the measurement step, since the measuring device during this period likewise measures the measuring coil winding. In the magnetic field detection step, a magnetic field camera can use its magneto-optical sensors to detect the magnetic flux density of the magnetic field.

A magnetic domain structure or Weiss domain at a surface of the test specimen can also be made visible using a suitable magneto-optical sensor device. Depending on the type of measurement, static images or dynamic images can be generated, by means of which domain wall shifts or domain rotations during a magnetization of the magnetizable test specimen can also be made visible and evaluated, for example in order to better be able to detect and ascertain the loss behavior of the magnetizable test specimen. The magnetization can be achieved here in different ways. For example, a DC pre-magnetization can also be performed before the high-current pulse is generated.

The disclosure also relates to a measuring system for determining a magnetic property of the magnetizable test specimen using the measuring device, wherein the measuring system has a measurement processing device which is connected to the measuring device for signal exchange therewith and by means of which the method according to the disclosure can be performed. The measurement processing device to this end can have, for example, a computer or a laptop, on which a suitably programmed evaluation software can be activated.

The calculated measuring coil core, test specimen and total power losses and further characteristic measurement data of the past measurement runs can be saved in the memory devices of the computer or of the laptop and may be necessary for quality control.

The following detailed description is merely exemplary in nature and is not intended to limit the invention or the application and uses of the invention. Furthermore, there is no intention to be bound by any theory presented in the preceding background or the following detailed description.

### BRIEF DESCRIPTION OF THE DRAWINGS

Hereinafter, schematic representations show exemplary embodiments of the invention.

FIG. 1 shows a measuring system for measuring magnetic properties and characteristic variables of a magnetizable test specimen using a measuring device, an energy supply device and a measurement processing device.

FIG. 2 shows two U-shaped measuring coil cores with a measuring coil winding and a test specimen arranged between them.

FIG. 3 shows a magnetizable test specimen with a measuring coil winding, a measuring coil core and a magnetic field camera.

FIG. 4 shows a sequential flowchart of the method for detecting magnetic properties of a magnetizable test specimen.

FIG. 5 shows a characteristic diagram of the measuring coil winding calculated by a method for detecting magnetic properties of a magnetizable test specimen.

FIG. 6 shows an alternative embodiment of the measuring system with a converter as energy supply device.

### DETAILED DESCRIPTION

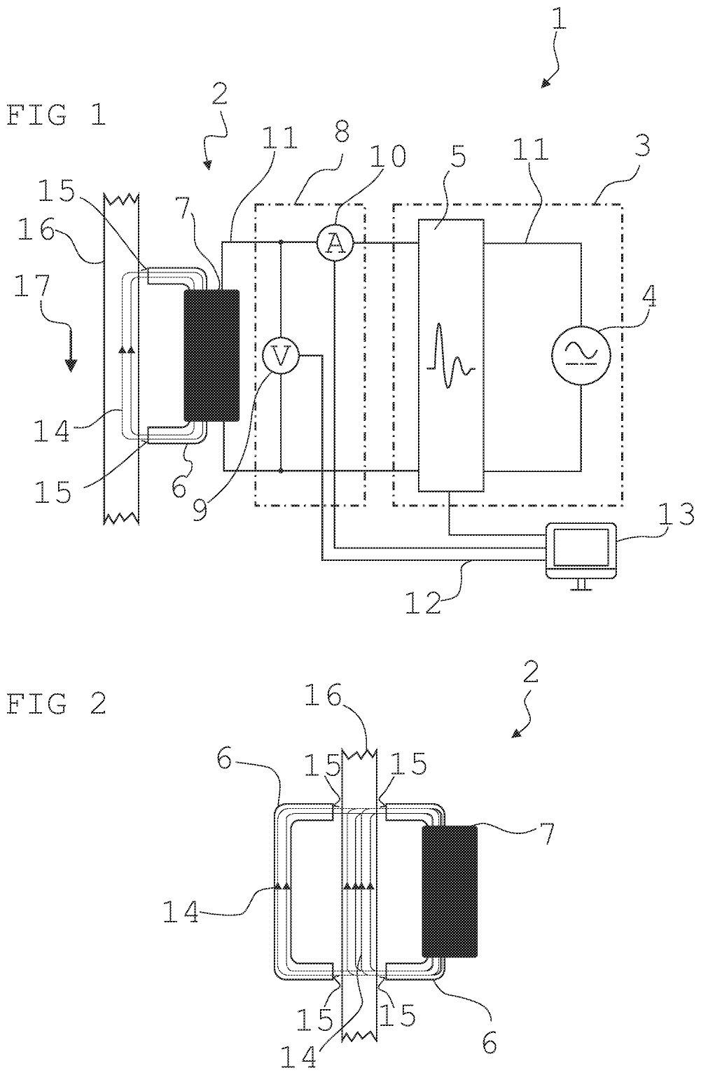

FIG. 1 shows a measuring system 1 according to the invention with a measuring device 2 according to the invention and an energy supply device 3. The energy supply device 3 comprises an energy source 4, which can provide both direct and alternating voltages, and a pulse generator 5, which, supplied by the energy source 4, can generate the high-current pulse.

By contrast, the measuring device 2 comprises a U-shaped measuring coil core 6, which is passed around by a measuring coil winding 7, and a sensor device 8, which has a voltage measurement point 9 and a current measurement point 10, wherein the sensor device 8 is suitable for detecting the electrical characteristic variables of the measuring coil winding 7. The measuring device 2 and the energy supply device 3, specifically the pulse generator 5, are connected to one another via electrical lines 11, so that the high-current pulse generated by the pulse generator 5 can act on the measuring coil winding 7, while the sensor device 8 can detect the electrical characteristic variables.

Furthermore, the current measurement point 10 and voltage measurement point 9 are connected via signal lines 12 to a measurement processing device in the form of a computer 13, so that the current and voltage profiles at the measuring coil winding 7 can be reliably processed and saved.

If a high-current pulse is applied to the measuring coil winding 7, a magnetic flux 14 forms in the measuring coil core 6 and runs along the measuring coil core 6 and exits and enters again from two magnetic flux passage faces 15.

If a test specimen 16 is arranged in the vicinity of the magnetic flux passages faces 15, the magnetic flux 14 also runs through the test specimen 16. In a reference measurement, the magnetic losses of the measuring coil core 6 can be ascertained when there is no test specimen 16 arranged at the magnetic flux passage faces 15. Wherein in a subsequent measurement run, which is performed with the test specimen 16 bearing against the magnetic flux passage faces 15, the total power loss from the test specimen 16 and the measuring coil core 6 can be ascertained. With the aid of mathematical calculation, the two power losses, that is to say a power loss of the test specimen 16 and also of the measuring coil core 6, can then be separated, whereby the magnetic quality of the test specimen 16 can then be rated.

As shown in FIG. 1, the test specimen 16, which is much longer along a movement direction 17 than the measuring coil core 6, can be moved along the movement direction 17. The magnetic power loss of the longer test specimen 16 can thus be measured in some portions of the test specimen with a regional resolution in a length of the measuring coil core 6.

The indirect measurement of the magnetic flux 14 via the electrical characteristic variables detected using the sensor device 8 can usually be achieved more precisely, more reliably or more economically than a direct measurement of the magnetic flux 14 via magnetic field sensors or the like. Furthermore, more detailed and complex calculations and visualization can be performed in the computer 13, so that more than just the magnetic flux 14 can be directly measured and evaluated.

An alternative embodiment of a region around the test specimen 16 is shown in FIG. 2. In this schematic illustration, the test specimen 16 on the one hand is likewise arranged at the two magnetic flux passage faces 15 of the measuring coil core 6, and on the other hand the measuring device 2 has a second U-shaped measuring coil core 6, which is arranged on the left side of the test specimen 16. This can be advantageous because the magnetic flux 14 generated by the high-current pulse can thus distribute better and more uniformly in the test specimen 16, since the magnetic flux 14 can likewise flow through the second measuring coil core 6.

Furthermore, the second measuring coil core 6 can also have its own measuring coil winding 7, which could generate an additional component of the magnetic flux 14 in the test specimen 16, however this is not explicitly shown in this illustration.

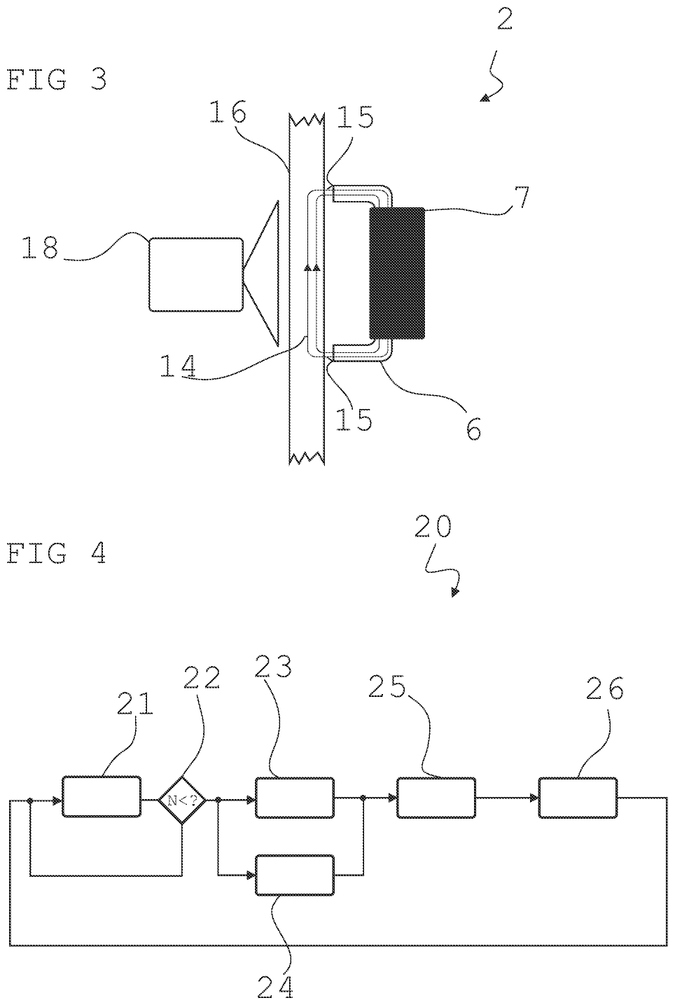

FIG. 3 shows a further embodiment of the measuring device 2, in which the second measuring coil core 6 has been replaced by a magneto-optical sensor device 18. By means of the magneto-optical sensor device 18, for example a magnetic field camera, the measuring device 2 can detect a magnetic flux density on a surface 19 of the test specimen 16 resulting from the magnetic flux 14 within the test specimen.

The magneto-optical sensor device 18 can be used to determine a distribution, a uniformity and an intensity of the magnetic flux density on the detected surface 19, which can be advantageous for a continuous quality control.

A flowchart of the method 20 according to the invention is shown schematically in FIG. 4. Here, a measurement process of the method 20 starts with a reference measurement step 21, in which the current and voltage profiles are detected by means of a sensor device 8, without a test specimen 16 being arranged at the magnetic flux passage faces 15 of the measuring coil core 6. Wherein the reference measurement step 21 can also be performed more than once by means of a branching 22 in accordance with a pre-setting. The repeated performance of the reference measurement step 21 makes it possible to form a reliable mean value of the electrical characteristic variables detected by the sensor device 8.

A measurement step 23 and a magnetic field protection step 24 are then performed in parallel. In the measurement step 23, the measuring coil winding 7 of the measuring device 2 is acted on by the high-current pulse and the electrical characteristic variables are detected by means of the sensor device 8 and current measurement point 10 and voltage measurement point 9 thereof. At the same time, a magnetic field camera 18 in the magnetic field detection step 24 detects the magnetic flux density of the surface 19 of the test specimen 16.

In a following calculation step 25, the respective losses of the measuring coil 6 and of the test specimen 16 are calculated, merged and/or visualized on the basis of the detected measurement data and characteristic variables.

In a last, movement step 26, the test specimen is moved in automated fashion in the movement direction 17 by a pre-set value, so that a new portion of the test specimen 16 can be measured in accordance with the method 20 according to the invention.

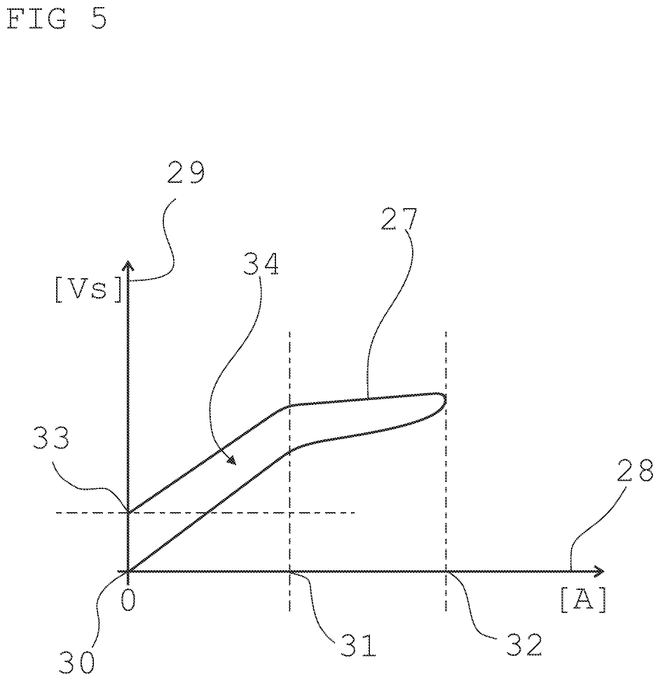

A function graph 27 resulting from the high-current pulse and detected and calculated by the measuring device 2 is shown schematically in FIG. 5. A current intensity through the measuring coil winding 7 detected by the sensor device 8 and current measurement point 10 thereof is plotted in amperes [A] along an abscissa 28, wherein integrated voltage-time values in volt seconds [Vs] of the voltage at the measuring coil winding 7 detected by a sensor device 8 and voltage measurement point 9 thereof are plotted along an ordinate 29.

The profile of the function graph 27 starts at a coordinate origin 30 and increases linearly to a saturation current value 31, after which the profile of the function graph 27 levels off significantly, since the measuring coil winding 7 is saturated, until at a peak current value 32 the profile of the function graph 27 reverses, since the high-current pulse likewise subsides. The subsiding high-current pulse causes a profile of the function graph 27 that descends in a reverse sequence and makes a stop, once the high-current pulse has subsided, at a residual magnetization value 33.

An enclosed energy area 34 of the function graph 27 has the unit of an energy (VAs) so that the magnetic losses of the performed measurement process can be determined via the enclosed energy area 34. After a plurality of measurement processes, with and without the test specimen 16, the ascertained total power losses can be allocated proportionally in computer-generated fashion to the test specimen 16 and the measuring coil core 6.

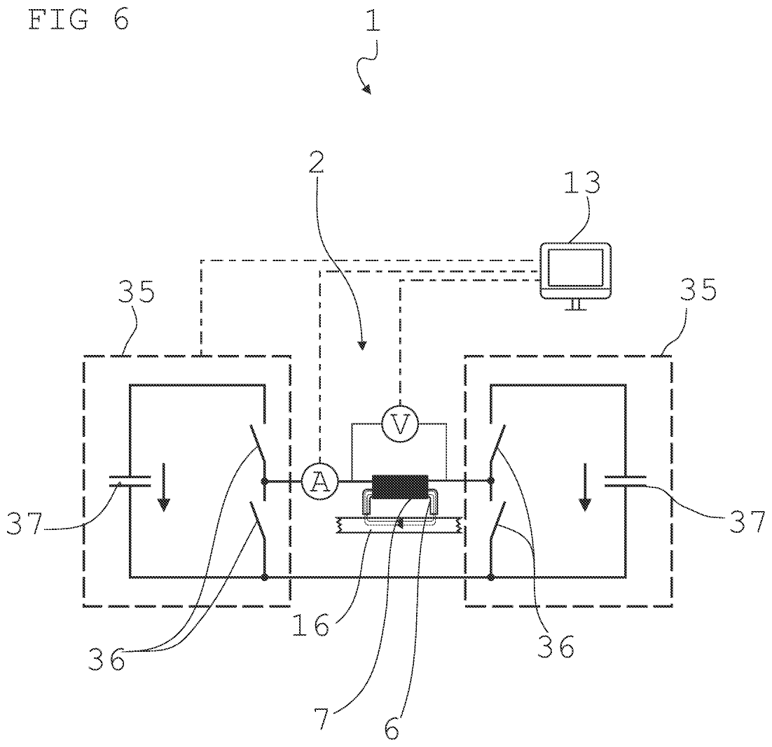

FIG. 6 shows an alternative embodiment of the measuring system 1 according to the invention with the measuring device 2, the energy supply device 3 and the computer 13. The energy supply device 3, in contrast to the previous figures, does not have a separate energy source 4 and no separate pulse generator 5. Both are now integrated in a converter 35.

The high-current pulse is provided in the shown illustration by four power semiconductor switches 36 interconnected to form an H-bridge circuit, wherein the energy for the high-current pulse can be drawn from a DC link 37, which in turn should be charged by an external energy source (not shown) for example a battery or a rectifier.

The differently formed high-current pulses can be generated by corresponding switch positions of the power semiconductor switches 36. The power semiconductor switches 36 in this case can be thyristors IGBTs or also MOSFETs.

While the present invention has been described with reference to exemplary embodiments, it will be readily apparent to those skilled in the art that the invention is not limited to the disclosed or illustrated embodiments but, on the contrary, is intended to cover numerous other modifications, substitutions, variations and broad equivalent arrangements that are included within the spirit and scope of the following claims.

The words “example” and “exemplary” as used herein mean serving as an instance or illustration. Any embodiment or design described herein as “example” or “exemplary” is not necessarily to be construed as preferred or advantageous over other embodiments or designs. Rather, use of the word example or exemplary is intended to present concepts in a concrete fashion. In addition, the articles “a” and “an” as used in this application and the appended claims should generally be construed to mean “one or more” unless specified otherwise or clear from context to be directed to a singular form.

### LIST OF REFERENCE SIGNS

1. measuring system

2. measuring device

3. energy supply device

4. energy source

5. pulse generator

6. measuring coil core

7. measuring coil winding

8. sensor device

9. voltage measurement point

10. current measurement point

11. electrical line

12. signal lines

13. measurement processing device/computer

14. magnetic flux

15. magnetic flux passage faces

16. test specimen

17. movement direction

18. magneto-optical sensor device

19. surface

20. method

21. reference measurement step

22. branch

23. measurement step

24. magnetic field detection step

25. calculation step

26. movement step

27. function graph

28. abscissa

29. ordinate

30. coordinate origin

31. saturation current value

32. peak current value

33. residual magnetization value

34. enclosed energy area

35. converter

36. power semiconductor

37. DC link

What is claimed is:

1. A measuring device (2) for determining magnetic properties of a magnetizable test specimen (16), comprising:
a measuring coil core (6) comprising magnetic flux passage faces (15) arranged at a distance from one another;
a measuring coil winding (7) which passes around the measuring coil core (6);
an energy supply device (3) configured to supply electrical energy to the measuring coil winding (7);
a sensor device (8) configured to detect a characteristic variable for the magnetic properties of the magnetizable test specimen (16),
wherein the energy supply device (3) is designed and set up in such a way that a high-current pulse can be generated by the energy supply device (3) and conducted through the measuring coil winding (7),
wherein the magnetizable test specimen (16) can be arranged adjacently to the magnet flux passage faces (15) during a measurement process in such a way that the high-current pulse conductable through the measuring coil winding (7) can bring about a magnetic flux (14) through the measuring coil core (6) and the magnetizable test specimen (16), and
wherein the sensor device is designed and set up in such a way that a temporal profile of electrical characteristic variables of the measuring coil winding (7) can be detected using the sensor device (8).

2. The measuring device (2) according to claim 1,
wherein the measuring coil core (6) consists of a material with high magnetic permeability.

3. The measuring device (2) according to claim 1,
wherein the magnetizable test specimen (16) is arranged movably at the magnetic flux passage faces (15).

4. The measuring device (2) according to claim 1,
wherein the measuring coil core (6) is U-shaped.

5. The measuring device (2) according to claim 1,
wherein the magnetic flux passage faces (15) of the measuring coil core (6) have a surface roughness with a mean roughness value of less than 0.5 μm.

6. The measuring device (2) according to claim 1, further comprising:
a second magnetizable measuring coil core (6), comprising further magnetic flux passage faces (15) which are arranged opposite the magnetic flux passage faces (15) of the magnetizable measuring coil core (6) passed around by the measuring coil winding (7),
wherein the magnetizable test specimen (16) can be arranged between the magnetic flux passage faces (15) and the further magnetic flux passage faces (15) in such a way that the magnetic flux (14) generated by the measuring coil winding (7) can be guided and can run through the measuring coil core (6) and the second magnetizable measuring coil core (6) and the magnetizable test specimen (16).

7. The measuring device (2) according to claim 1,
wherein the measuring device (2) comprises a magneto-optical sensor device (18) configured to optically detect a magnetization of the magnetizable test specimen (16).

8. The measuring device (2) according to claim 1,
wherein the measuring coil winding (7) consists of multicore lines, and
wherein the multicore lines are electrically insulated with respect to one another.

9. A method (20) for ascertaining a magnetic property of a magnetizable test specimen (16), comprising:
arranging, in a measurement step (23), the magnetizable test specimen in a measurement position relative to a measuring coil core with a measuring coil winding of a measuring device (2) passing around the measuring coil core;
using an energy supply device (3), which is electrically conductively connected to the measuring device (2), to guide a high-current pulse created by the energy supply device (3) through the measuring coil winding (7) of the measuring device (2);
detecting a temporal current and voltage profile through the measuring coil winding (7);
ascertaining, in a subsequent ascertainment step (25), a characteristic value for a magnetic property of the test specimen (16) based on the detected current and voltage profile by comparing the current and voltage profile, detected with the magnetizable test specimen, for the magnetizable test specimen (16) and the measuring device (2) with a corresponding profile of a reference current profile and reference voltage profile; and
ascertaining a characteristic variable for the magnetic property of the test specimen (16) from a difference between the measured current profile and voltage profile and the reference current profile and reference voltage profile.

10. The method (20) according to claim 9,
wherein the high-current pulse generated by the energy supply device (3) and guided through the measuring coil winding (7) is predefined such that a magnetic flux generated in the magnetizable test specimen by the high- current pulse is adapted to a magnetic saturation of the magnetizable test specimen (16).

11. The method (20) according to claim 9, further comprising:
moving, in a movement step (26), the magnetizable test specimen (16) relative to magnetic flux passage faces (15) of the measuring coil core (6).

12. The method (20) according to claim 9, further comprising:
detecting, in a magnetic field detection step (24), a magnetic flux density of the magnetic field by a magneto-optical sensor device (18) at a surface of the test specimen (16).
